(19) United States
(12) Patent Application Publication
(10) Pub. No.: US 2018/0151830 A1
(43) Pub. Date: May 31, 2018

(54) DISPLAY DEVICE AND ELECTRONIC DEVICE

(71) Applicant: CANON KABUSHIKI KAISHA, Tokyo (JP)

(72) Inventors: Mariko Furuta, Yokohama-shi (JP); Nobutaka Ukigaya, Yokohama-shi (JP)

(21) Appl. No.: 15/816,371

(22) Filed: Nov. 17, 2017

(30) Foreign Application Priority Data
Nov. 30, 2016 (JP) 2016-233498
Oct. 27, 2017 (JP) 2017-208514

(51) Int. Cl. H01L 51/52; H01L 27/32; H01L 51/00

(52) U.S. Cl. CPC H01L 51/5218; H01L 27/3246; H01L 27/3248; H01L 2251/5315; H01L 51/0023; H01L 2227/323; H01L 51/5209

(57) ABSTRACT

A display device includes an electrode structure including a first electrode arranged on a substrate and a member arranged on the first electrode, an insulator configured to cover a peripheral portion of the electrode structure, an organic film configured to cover the first electrode and the insulator, and a second electrode configured to cover the organic film. The member includes a first portion arranged in the peripheral portion of the electrode structure so as to cover a peripheral portion of an upper face of the first electrode, and a reflectance of the peripheral portion of the electrode structure is lower than a reflectance of a central portion that is a portion inside the peripheral portion of the electrode structure.

### BACKGROUND OF THE INVENTION

### Field of the Invention

The present invention relates to a display device and an electronic device.

### Description of the Related Art

In recent years, an organic EL display device that is a self-emission device including an organic EL element has received attention as a flat panel display. A display device including a first electrode, an insulating film that covers the peripheral portion of the first electrode, an organic layer that covers the first electrode and the insulating film, and a second electrode that covers the organic layer is described in Japanese Patent Laid-Open No. 2012-216495. Japanese Patent Laid-Open No. 2012-216495 describes that the first electrode can have a structure in which a 15-nm thick aluminum film is stacked on a 20-nm thick titanium, tungsten, copper, tantalum, or molybdenum film.

In the display device described in Japanese Patent Laid-Open No. 2012-216495, the peripheral portion of the first electrode covered with the insulating film does not inject charges into the organic layer and therefore does not contribute to light emission. On the other hand, the peripheral portion of the first electrode of a certain pixel can reflect light generated by the organic layer at an upper position of the first electrode and make the light enter an adjacent pixel. This light is called stray light and can lower the resolution or cause color mixture in a color display device. In particular, if the upper face of the first electrode is made of a metal material having a high reflectance to increase the reflectance of the first electrode, as in the display device described in Japanese Patent Laid-Open No. 2012-216495, occurrence of such resolution lowering or color mixture can be more conspicuous.

### SUMMARY OF THE INVENTION

The present invention provides a display device having a structure advantageous to suppress occurrence of resolution lowering and/or color mixture.

One of aspects of the present invention provides a display device comprising: an electrode structure including a first electrode arranged on a substrate, and a member arranged on the first electrode; an insulator configured to cover a peripheral portion of the electrode structure; an organic film configured to cover the first electrode and the insulator; and a second electrode configured to cover the organic film, wherein the member includes a first portion arranged in the peripheral portion of the electrode structure so as to cover a peripheral portion of an upper face of the first electrode, and a reflectance of the peripheral portion of the electrode structure is lower than a reflectance of a central portion that is a portion inside the peripheral portion of the electrode structure.

Further features of the present invention will become apparent from the following description of exemplary embodiments with reference to the attached drawings.

### BRIEF DESCRIPTION OF THE DRAWINGS

FIG. 1 is a view schematically showing the sectional structure of a display device (organic EL display device) according to the first embodiment of the present invention;

FIG. 2 is a view showing the arrangement of an organic film in the display device shown in FIG. 1;

FIG. 3 is a view showing the orthogonal projection of a connection plug and an electrode structure to the surface of a substrate;

FIG. 4 is a view showing the arrangement of a display device according to a comparative example;

FIG. 5 is a schematic view for explaining suppression of stray light in the display device according to the first embodiment of the present invention;

FIG. 6 is a view showing the sectional structure of a display device according to the second embodiment of the present invention;

FIG. 7 is a view showing the sectional structure of a display device according to the third embodiment of the present invention;

FIG. 8 is a view showing the sectional structure of a display device according to the fourth embodiment of the present invention;

FIG. 9 is a view showing the sectional structure of a display device according to the fifth embodiment of the present invention;

FIGS. 10A to 10C are views showing the arrangement of the display device according to the fifth embodiment of the present invention;

FIGS. 11A and 11B are views showing a method of manufacturing the display device according to the embodiment of the present invention;

FIGS. 12A and 12B are views showing a method of manufacturing the display device according to the embodiment of the present invention;

FIG. 13 is a plan view of the display device according to the first embodiment of the present invention;

FIG. 14 is a plan view of a display device according to the sixth embodiment of the present invention;

FIG. 15 is a view showing the sectional structure of the display device according to the sixth embodiment of the present invention; and

FIG. 16 is a view showing an example of an electronic device including the display device according to the present invention.

### DESCRIPTION OF THE EMBODIMENTS

The present invention will now be described with reference to the accompanying drawings by way of embodiments.

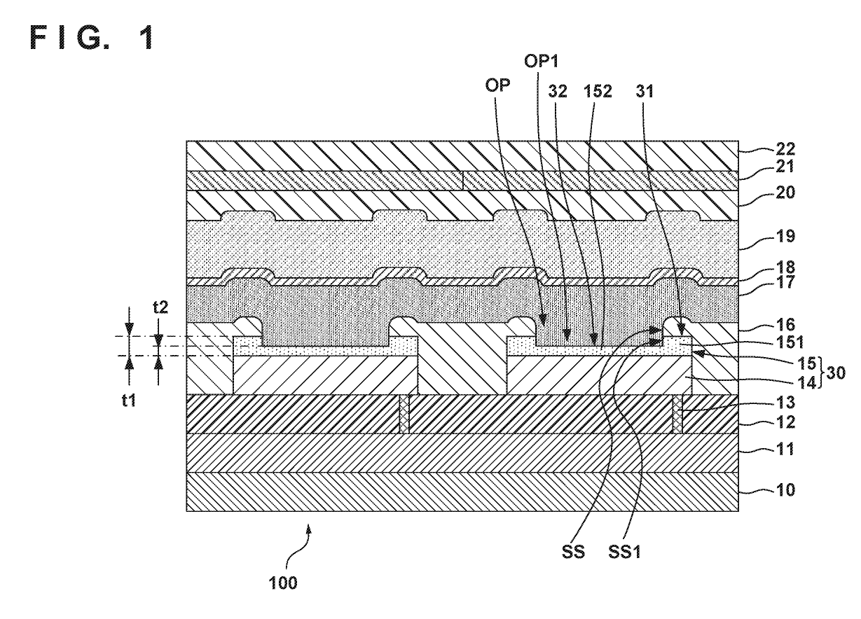

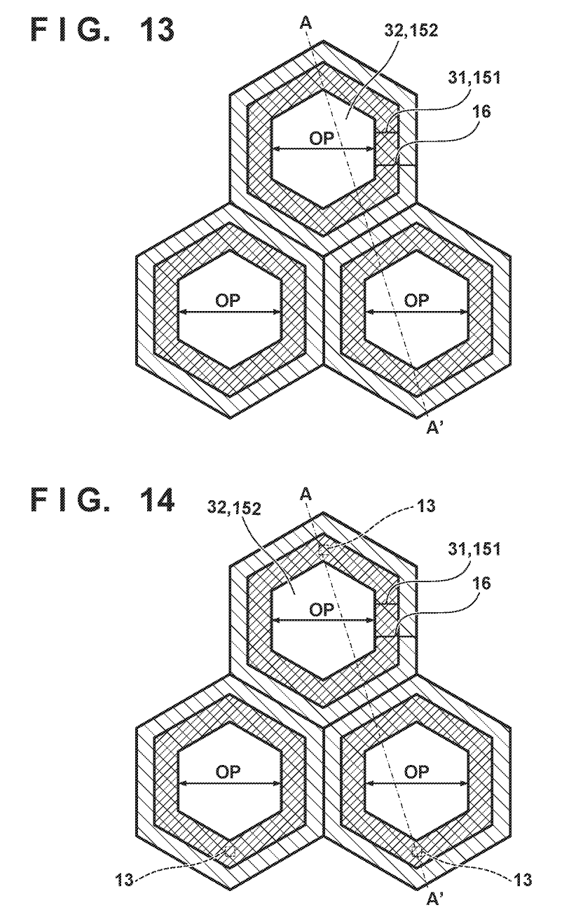

FIG. 1 schematically shows the sectional structure of a display device (organic EL display device) 100 according to the first embodiment of the present invention. FIG. 13 is a plan view (layout diagram) of the display device 100 according to the first embodiment. FIG. 1 corresponds to a sectional view taken along a line A-A′ in FIG. 13. Although FIG. 1 shows only two pixels, and FIG. 13 shows only three pixels, the display device 100 can include more pixels. Each pixel includes an organic EL element. The display device 100 can include a substrate 10, a driving circuit layer 11 arranged on the substrate 10, a first planarizing layer 12 that covers the driving circuit layer 11, and a plurality of electrode structures 30 arranged on the first planarizing layer 12. The driving circuit layer 11 includes a plurality of driving circuits, and each driving circuit drives the electrode structure 30 of a corresponding pixel. Each electrode structure 30 can include a first electrode 14 arranged on the substrate 10 (first planarizing layer 12), and a member 15 arranged on the first electrode 14. In each of the plurality of electrode structures 30, the member 15 includes a first portion 151 arranged on a peripheral portion 31 of the electrode structure 30 so as to cover the peripheral portion of the upper face of the first electrode 14. Additionally, in each of the plurality of electrode structures 30, the member 15 can include a second portion 152 arranged at a central portion 32 of the electrode structure 30 so as to cover the central portion of the upper face of the first electrode 14. The reflectance of the peripheral portion 31 of the electrode structure 30 is lower than the reflectance of the central portion 32 that is a portion inside the peripheral portion 31 of the electrode structure 30.

The substrate 10 may be an insulating substrate such as a glass substrate, may be a conductive substrate such as a metal substrate, or may be a semiconductor substrate such as a silicon substrate. Each of the plurality of driving circuits of the driving circuit layer 11 can include a transistor such as a TFT or MOSFET. If the substrate 10 is an insulating substrate such as a glass substrate, the transistor can be arranged on the substrate 10. If the substrate 10 is a semiconductor substrate, the active region of the transistor can be formed in the semiconductor substrate. The first planarizing layer 12 can be made of, for example, an inorganic material such as silicon oxide or silicon nitride because if moisture content is low. However, the first planarizing layer 12 may be made of an organic material.

The display device 100 can include an insulator 16 that covers the peripheral portion 31 of each of the plurality of electrode structures 30, an organic film 17 that covers the first electrode 14 of each of the plurality of electrode structures 30 and the insulator 16, and a second electrode 18 arranged to cover the organic film 17. In the first planarizing layer 12, a connection plug 13 that connects each driving circuit of the driving circuit layer 11 to a corresponding electrode structure 30 (first electrode 14) can be arranged. The insulator 16 can be arranged to separate the plurality of electrode structures 30 from each other. One pixel includes one electrode structure 30. The organic film 17 and the second electrode 18 can be shared by a plurality of pixels. The display device 100 can include, for example, a plurality of R pixels (red pixels), a plurality of G pixels (green pixels), and a plurality of B pixels (blue pixels).

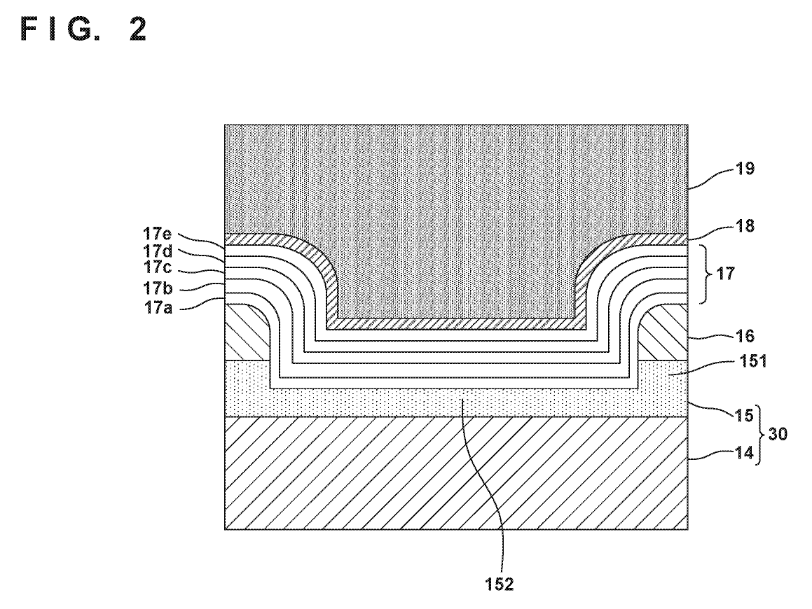

FIG. 2 shows an example of the arrangement of the organic film 17. The organic film 17 can have an arrangement in which, for example, a hole injection layer 17a, a hole transport layer 17b, an emission layer 17c, an electron transport layer 17d, and an electron injection layer 17e are sequentially stacked on the electrode structure 30. Light generated by the emission layer 17c can be extracted to the outside via the second electrode 18. The hole injection layer 17a can be arranged to cover the member 15 and the insulator 16. The hole injection layer 17a can cover the side face of the first portion 151 and the surface of the second portion 152.

The display device 100 can include a first protection layer 19 that covers the second electrode 18, a second planarizing layer 20 that covers the first protection layer 19, a color filter layer 21 arranged on the second planarizing layer 20, and a second protection layer 22 arranged on the color filter layer 21.

Each pixel has a size of, for example, about 1 to 5 μm. The interval between the adjacent electrode structures 30 can be, for example, 0.1 to 1 μm. For example, if the thickness of the organic film 17 is about 0.05 to 0.2 μm, it is necessary to prevent light generated by the emission layer 17c from mixing between adjacent pixels.

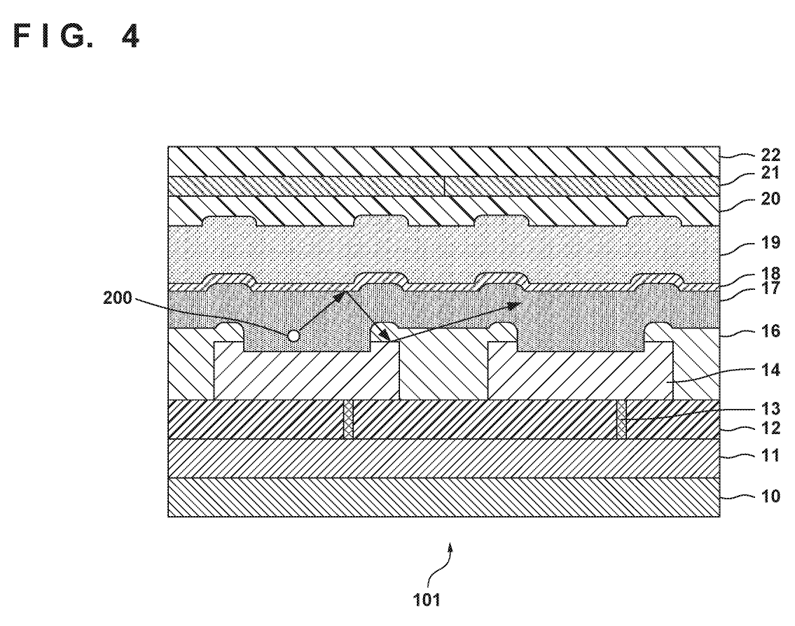

FIG. 4 shows the arrangement of a display device 101 according to a comparative example. The display device 101 according to the comparative example is different from the display device 100 according to the first embodiment shown in FIG. 1 in that the member 15 is not provided on the first electrode 14. In the display device 101 according to the comparative example, light generated by the organic film 17 at an upper position 200 of the first electrode 14 of a certain pixel can be reflected by the first electrode 14 and the second electrode 18 and thus result in stray light and enter an adjacent pixel. Accordingly, resolution lowering or color mixture can occur.

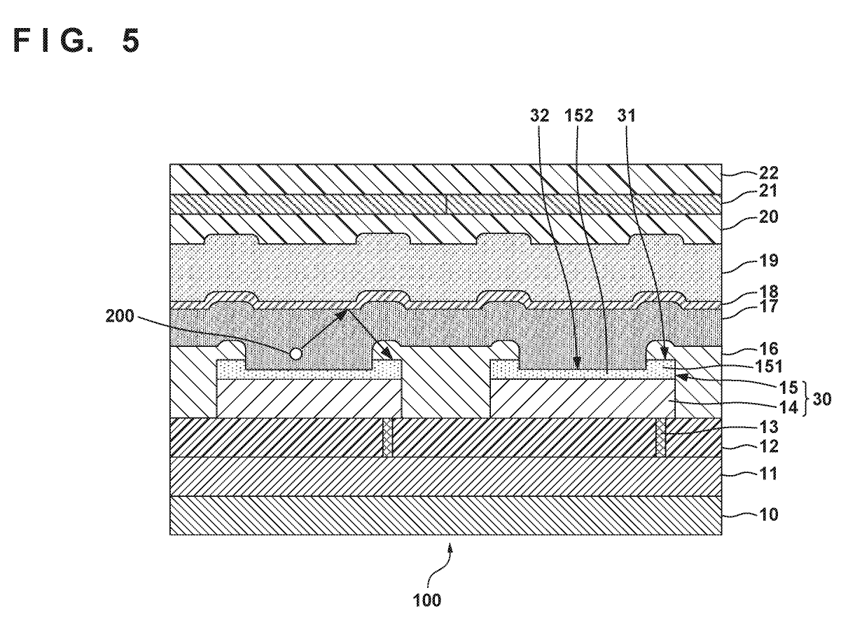

On the other hand, in the display device 100 according to the first embodiment, the member 15 is provided on the first electrode 14. The reflectance of the peripheral portion 31 of the electrode structure 30 is thus made lower than that of the central portion 32 of the electrode structure 30. Hence, as schematically shown in FIG. 5, in the display device 100 according to the first embodiment, light generated by the organic film 17 at the upper position 200 of the electrode structure 30 (first electrode 14) of a certain pixel is suppressed from being reflected by the electrode structure 30 and resulting in stray light. Hence, the display device 100 according to the first embodiment is advantageous to suppress resolution lowering or color mixture.

The first electrode 14 can contain a high-reflectance material, for example, at least one of aluminum, silver, an aluminum alloy, and a silver alloy. The first electrode 14 may be formed by a single layer or may be formed by a plurality of layers. For example, a Ti layer or a Ti layer/TiN layer can be provided under an aluminum layer, thereby strengthening the orientation of the aluminum layer and improving the planarity of the aluminum layer. A layer that does not largely impede reflection performance, for example, a transparent layer such as an ITO layer or an IZO layer may be formed on the surface of the aluminum layer.

The member 15 in the electrode structure 30 can contain a material having a reflectance lower than that of the first electrode 14, for example, at least one of titanium (Ti) and titanium nitride (TiN). From another point of view, the member 15 in the electrode structure 30 can be made of a conductive material such as a metal or a metallic compound, which is a material having a reflectance lower than that of the first electrode 14.

In the member 15 of the electrode structure 30, the first portion 151 is thicker than the second portion 152 (the second portion 152 is thinner than the first portion 151). For example, the difference between a thickness t1 of the first portion 151 and a thickness t2 of the second portion 152 is 5 nm or more (t1>t2). Making the thickness t1 of the first portion 151 larger than the thickness t2 of the second portion 152 is advantageous in making the reflectance of the peripheral portion 31 of the electrode structure 30 lower than the reflectance of the central portion 32 of the electrode structure 30. The upper limit of the difference between the thickness of the first portion 151 and the thickness of the second portion 152 can be determined in accordance with the thickness of the organic film 17 or the like.

Letting the energy of visible light entering the electrode structure 30 be 100%, the intensity of the visible light reflected by the central portion 32 of the electrode structure 30 is preferably larger than the energy of the visible light reflected by the peripheral portion 31 of the electrode structure 30 by 5 points or more. The visible light is light whose wavelength ranges from 400 nm to 700 nm. In an example, the member 15 is made of titanium, and the difference between the thickness t1 of the first portion 151 and the thickness t2 of the second portion 152 is 5 nm or more (t1>t2).

The reflectance of the central portion 32 of the electrode structure 30 is preferably high. To raise the reflectance of the central portion 32, the thickness of the second portion 152 is preferably 8 nm or less.

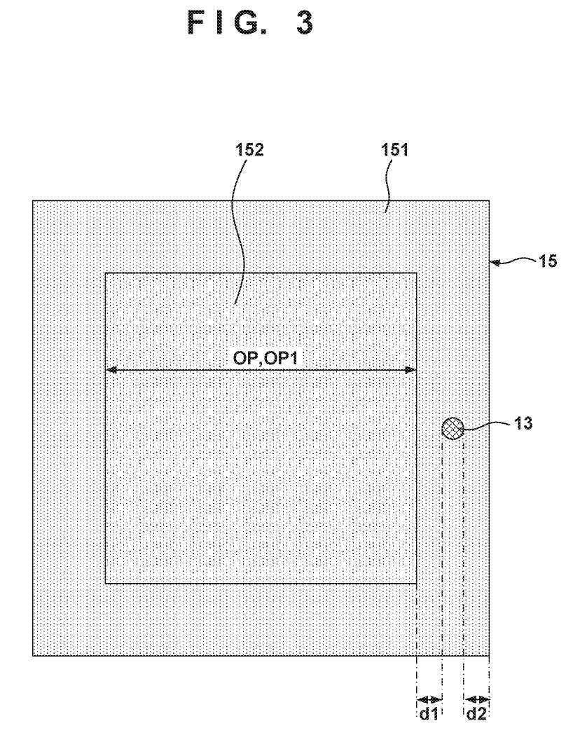

FIG. 3 shows the orthogonal projection of the connection plug 13 and the electrode structure 30 (member 15) to the surface of the substrate 10. As shown in FIG. 3, the connection plug 13 can be arranged in the region of the first portion 151 of the member 15 in the orthogonal projection to the surface of the substrate 10. This arrangement is advantageous in including, in the peripheral portion 31 where the reflectance is lower than the central portion 32, unevenness that can be formed on the surface of the electrode structure 30 because of the existence of the connection plug 13. The existence of unevenness on the surface of the electrode structure 30 may cause stray light to a pixel adjacent to the pixel including the electrode structure 30. Such stray light can be suppressed by including, in the peripheral portion 31 with the low reflectance, the unevenness that can be formed on the surface of the electrode structure 30.

The insulator 16 can have an opening OP at a position overlapping the first opening OP1 in a planar view. The opening OP1 exposes the central portion 32 of the electrode structure 30. The organic film 17 can include a portion arranged in the opening OP. In the orthogonal projection to the surface of the substrate 10, a shortest distance d1 between the opening OP and the connection plug 13 is preferably 0.1 μm (inclusive) to 0.5 μm (inclusive). Additionally, in the orthogonal projection to the surface of the substrate 10, a shortest distance d2 between the connection plug 13 and the outer edge of the first electrode 14 is preferably 0.1 μm (inclusive) to 0.5 μm (inclusive). The first portion 151 of the member 15 includes a first opening OP1. The organic film 17 can include a portion arranged in the first opening OP1 so as to be in contact with a side face SS of the first portion 151 facing the first opening OP1. The organic film 17 covers the side face SS of the first portion 151 and the upper face of the second portion 152 so as to be in contact with the side face SS of the first portion 151 and the upper face of the second portion 152. The organic film 17 preferably contacts the entire region of the side face SS of the first portion 151 and the entire region of the upper face of the second portion 152. This arrangement is advantageous in reducing variations in the thickness and area of the organic film 17 between the pixels and equalizing the emission characteristics.

The member 15 that forms the electrode structure 30 may be made of a material (inorganic material or organic material) other than the above-described conductive material such as a metal or a metallic compound. The material can be selected in consideration of the charge injection efficiency to the organic film 17.

The insulator 16 may be made of, for example, an inorganic material such as silicon oxynitride, silicon oxide, or silicon nitride, an organic material such as acryl or polyimide, or another material.

The second electrode 18 is a transparent electrode and can be formed to cover the organic film 17 (electron injection layer 17e). The second electrode 18 can be made of a metal or a metal alloy. The second electrode 18 can be made of, for example, an alloy of magnesium and silver or an alloy of aluminum, sodium, and calcium. Alternatively, the second electrode 18 can be made of ITO or IZO.

The organic film 17 can include a portion arranged in the first opening OP1 so as to be in contact with side face SS1 of the first portion 151 of the member 15 of the electrode structure 30 facing the first opening OP1.

At the boundary between the first portion 151 and the insulator 16, the side face SS of the opening OP of the insulator 16 and the side face SS1 of the first opening OP1 of the first portion 151 can form a continuous surface. From another point of view, the maximum size of the first opening OP1 of the first portion 151 in a direction parallel to the surface of the substrate 10 may be less than or equal to the maximum size of the opening OP of the insulator 16 in the direction.

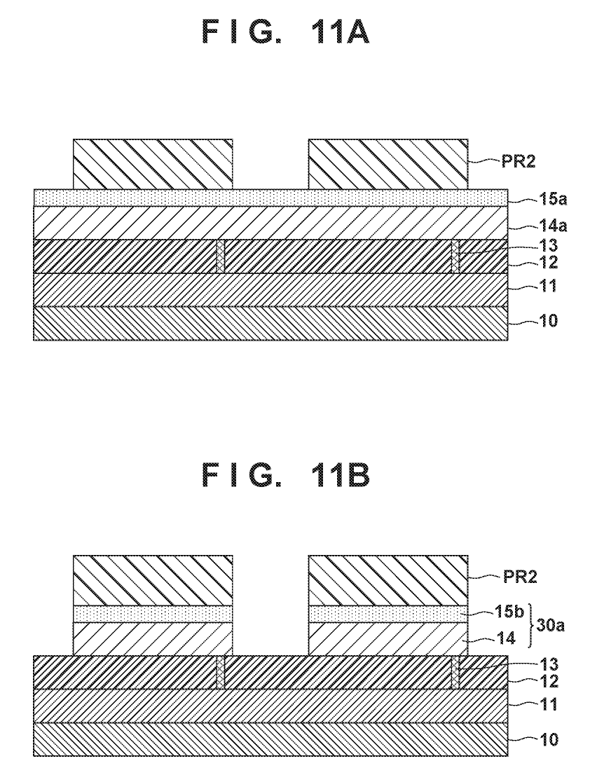

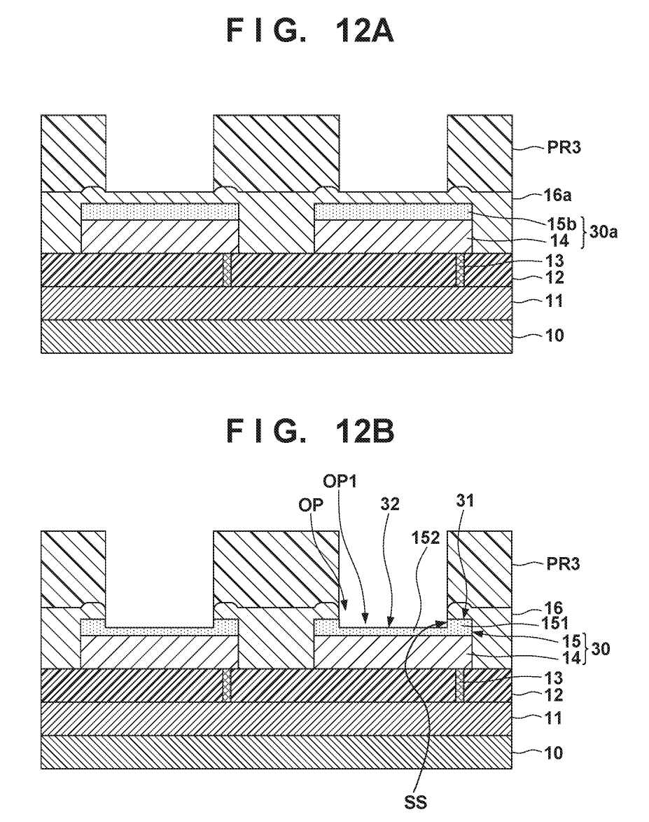

A method of manufacturing the display device 100 will be described with reference to FIGS. 11A, 11B, 12A, and 12B. A description will be made first with reference to FIG. 11A. The substrate 10 is prepared, and the driving circuit layer 11 including a driving circuit is formed on the substrate 10. Next, the first planarizing layer 12 is formed on the driving circuit layer 11 by a film formation method such as CVD or sputtering. Next, the first planarizing layer 12 is coated with a photosensitive resin, and the photosensitive resin is exposed and developed, thereby forming a first etching mask. The first planarizing layer 12 is etched via the openings of the first etching mask to form through holes. The through holes are filled with a conductive material, thereby forming the connection plugs 13. Next, to form the first electrode 14, a first material film 14a is formed on the first planarizing layer 12 and the connection plugs 13 by a film formation method such as vapor deposition or sputtering. Next, a second material film 15a used to form the member 15 is formed on the first material film 14a by a film formation method such as sputtering.

A description will be made next with reference to FIG. 11B. The second material film 15a is coated with a photosensitive resin, and the photosensitive resin is exposed and developed, thereby forming a second etching mask PR2. The first material film 14a and the second material film 15a are patterned (etched) using the second etching mask PR2. Electrode structures 30a each formed by the first electrode 14 and a member 15b (member layer) on the first electrode 14 are thus formed. The first electrode 14 is a film obtained by patterning the first material film 14a, and the member 15b is a film formed by patterning the second material film 15a.

A description will be made next with reference to FIG. 12A. The second etching mask PR2 is removed, and a third material film 16a (insulating film) used to form the insulator 16 is formed by a film formation method such as CVD so as to cover the electrode structures 30a. Next, the third material film 16a is coated with a photosensitive resin, and the photosensitive resin is exposed and developed, thereby forming a third etching mask PR3.

A description will be made next with reference to FIG. 12B. The third material film 16a (insulating film) is patterned (etched) using the third etching mask PR3, thereby forming the insulator 16 (insulating layer). This patterning is performed such that a part of a portion of the third material film 16a (insulating film) overlapping the first electrode 14 in a planar view is removed. With this patterning, the openings OP conforming to the openings of the third etching mask PR3 are formed in the insulator 16. When each opening OP is formed by patterning the third material film 16a, the member 15b is exposed to the opening OP.

After that, the central portion of each member 15b is etched via the opening OP to form an opening, thereby forming the member 15. This etching may be done under an etching condition in which the etch selectivity of the member 15b to the insulator 16 (third material film 16a) is 5 or more. After the member 15b is exposed, the etch selectivity may be adjusted by changing the RF power of the etching apparatus.

In addition, the member 15b may partially be removed by etching next to the etching for forming the opening OP in the third material film 16a. When the step of forming the opening OP of the insulator 16 and the step of forming the first opening OP1 of the member 15 are performed as one etching step, the efficiency of the manufacturing step can be increased.

The member 15 includes the second portion 152 having a surface etched using the third etching mask PR3, and the first portion 151 arranged outside the second portion 152 and having a thickness larger than that of the second portion 152. The first portion 151 includes the first opening OP1.

In an example, if the thickness of the first portion 151 is 7 nm, and the thickness of the second portion 152 is 5 nm, the reflectance of the first portion 151 in a case of incidence of light with a wavelength of 450 nm is higher than the reflectance of the second portion 152 by about 5 percent points. Note that in this example, the reflectance of the first electrode 14 in a case of absence of the member 15 is 90%.

A description will be made below with reference to FIG. 1. The third etching mask PR3 is removed, and the organic film 17 (the hole injection layer 17a, the hole transport layer 17b, the emission layer 17c, the electron transport layer 17d, and the electron injection layer 17e) is formed by a film formation method such as vacuum deposition, sputtering, or spin coating. Next, the second electrode 18 is formed on the organic film 17 by a film formation method such as vapor deposition or sputtering.

Next, the first protection layer 19 is formed on the second electrode 18 by a film formation method such as CVD or sputtering. The first protection layer 19 can be made of, for example, a low transparency material such as silicon nitride. The temperature when forming the first protection layer 19 is preferably 200° C. or less and more preferably 120° C. or less. Next, the second planarizing layer 20 is formed on the first protection layer 19 by a film formation method such as spin coating. The second planarizing layer 20 can be made of, for example, an organic material.

Next, the filter layer 21 including color filters of a plurality of colors is formed on the second planarizing layer 20. The color filter of each color can be formed by coating the second planarizing layer 20 with a filter material using spin coating or the like, patterning the coat by photolithography, and calcining it. Next, the second protection layer 22 is formed on the color filter layer 21 by a film formation method such as CVD or spin coating.

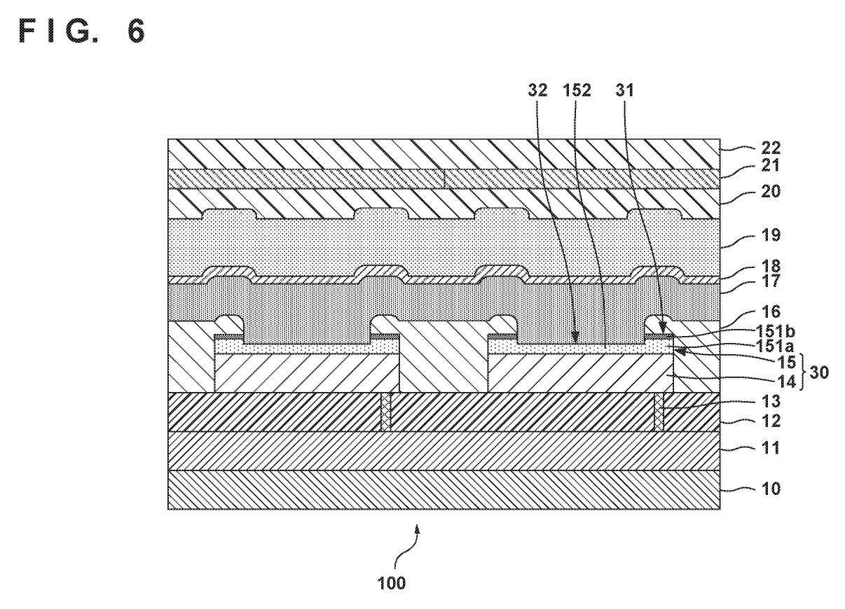

A display device 100 according to the second embodiment of the present invention will be described with reference to FIG. 6. Matters that are not mentioned as the second embodiment can comply with the first embodiment. In the second embodiment, a member 15 arranged on a first electrode 14 includes a first portion 151a outside a second portion 152. In addition, an electrode structure 30 includes a third portion 151b on the first portion 151a. A peripheral portion 31 of the electrode structure 30 thus includes an antireflection portion having a two-layered structure formed by the first portion 151a and the third portion 151b on the first electrode 14. In an example, the first portion 151a can be made of Ti, and the third portion 151b can be made of TiN. In the second embodiment as well, the reflectance of the peripheral portion 31 of the electrode structure 30 is lower than the reflectance of a central portion 32 of the electrode structure 30.

In an example, the second portion 152 arranged at the central portion 32 can have a thickness of 5 to 10 nm, and the first portion 151a arranged in the peripheral portion 31 can have a thickness larger than that of the second portion 152 by 0.1 nm or more. The third portion 151b can have a thickness of 1 nm or more.

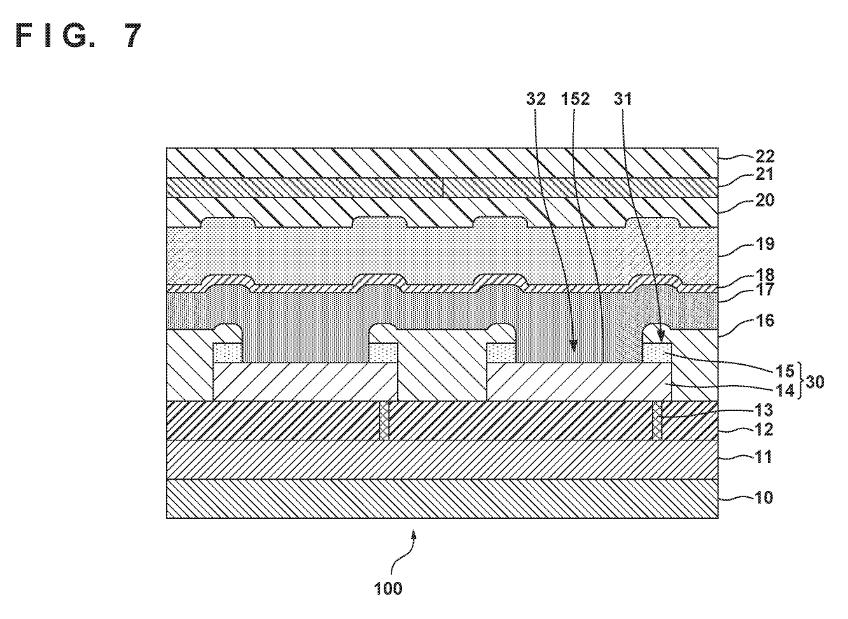

A display device 100 according to the third embodiment of the present invention will be described with reference to FIG. 7. Matters that are not mentioned as the third embodiment can comply with the first or second embodiment. In the third embodiment, a member 15 is not arranged at a central portion 32 of an electrode structure 30. That is, at the central portion 32, a first electrode 14 is in contact with an organic film 17. In the third embodiment as well, the reflectance of a peripheral portion 31 of the electrode structure 30 is lower than the reflectance of the central portion 32 of the electrode structure 30. In an example, the first member 15 arranged in the peripheral portion 31 can have a thickness of 5 to 10 nm.

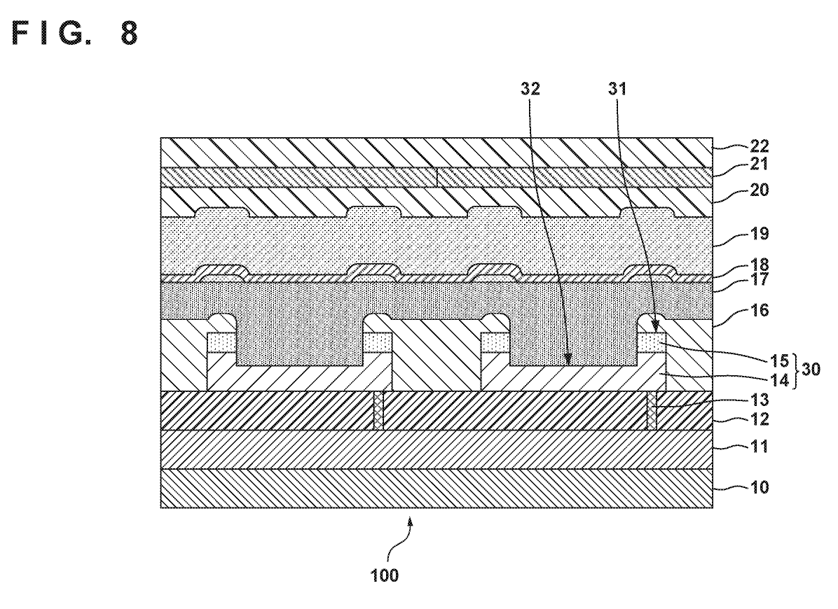

A display device 100 according to the fourth embodiment of the present invention will be described with reference to FIG. 8. Matters that are not mentioned as the fourth embodiment can comply with the first to third embodiments. In the fourth embodiment, a member 15 is not arranged at a central portion 32 of an electrode structure 30, as in the third embodiment.

Additionally, in the fourth embodiment, the thickness of a first electrode 14 at the central portion 32 is smaller than the thickness of the first electrode 14 in a peripheral portion 31. In the fourth embodiment as well, the reflectance of the peripheral portion 31 of the electrode structure 30 is lower than the reflectance of the central portion 32 (first electrode 14) that is a portion inside the peripheral portion 31 of the electrode structure 30.

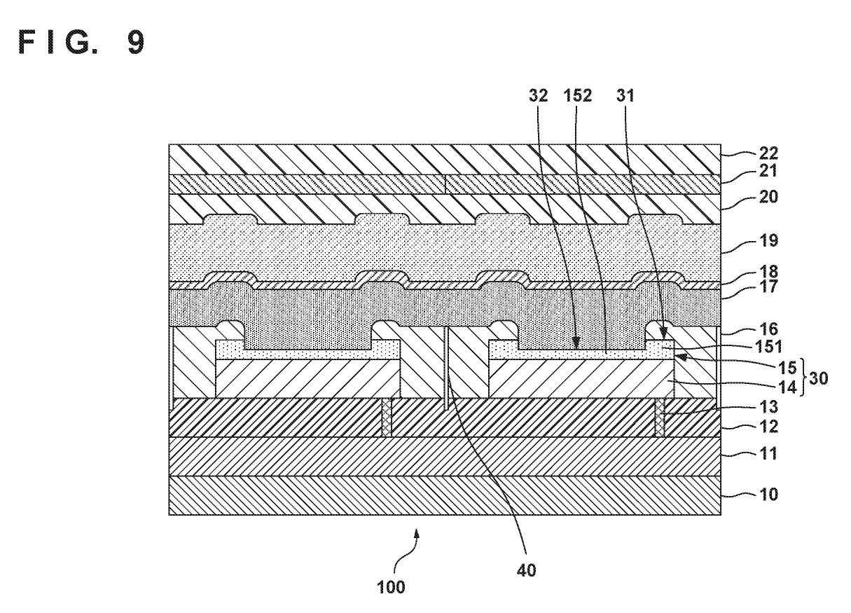

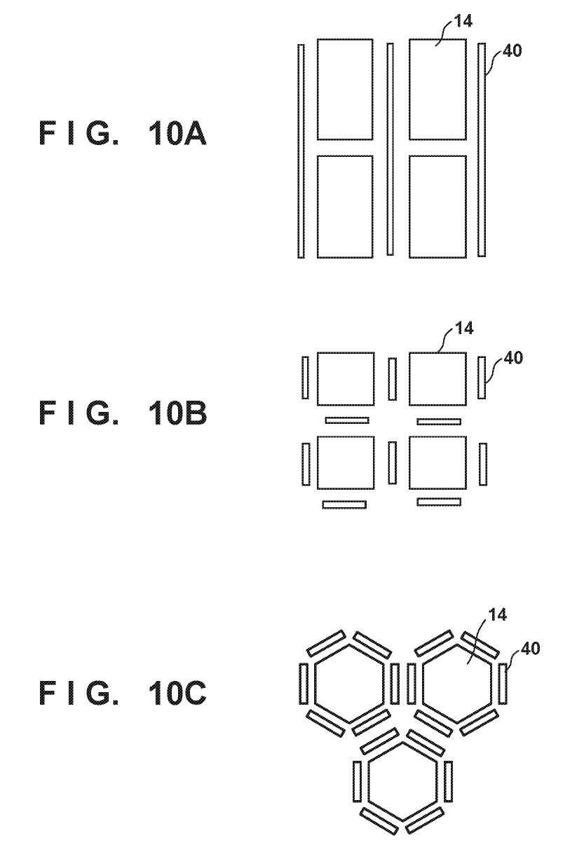

A display device 100 according to the fifth embodiment of the present invention will be described with reference to FIGS. 9 and 10A to 10C. Matters that are not mentioned as the fifth embodiment can comply with the first to fourth embodiments. In the display device 100 according to the fifth embodiment, an insulator 16 includes a trench 40 arranged between electrode structures 30 adjacent to each other in the plurality of electrode structures 30. When the trench 40 is provided, stray light between pixels can be reduced. FIGS. 10A to 10C are plan views (orthogonal projection to the surface of a substrate 10) of first electrodes 14 (electrode structures 30) and the trenches 40. As shown in FIGS. 10A to 10C, the first electrodes 14 (electrode structures 30) and the trenches 40 can have various structures.

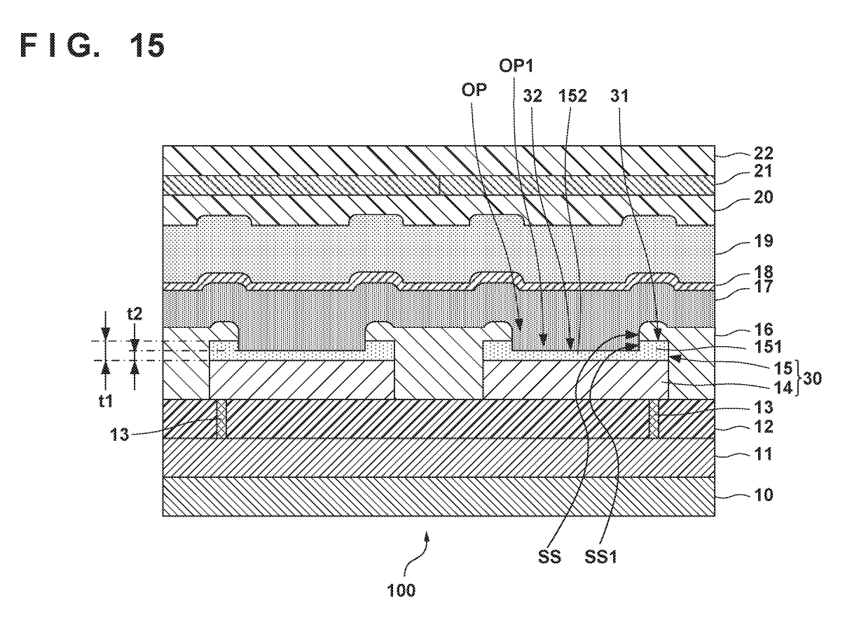

FIGS. 14 and 15 show a display device 100 according to the sixth embodiment of the present invention. FIG. 14 is a plan view (layout diagram) of the display device 100 according to the sixth embodiment. FIG. 15 schematically shows the sectional structure of the display device 100 according to the sixth embodiment. FIG. 15 corresponds to a sectional view taken along a line A-A′ in FIG. 14. Matters that are not mentioned as the sixth embodiment can comply with the first embodiment. In the sixth embodiment, the positions of connection plugs 13 are different from the first embodiment. The display device 100 according to each of the second to fifth embodiments can also be modified to have the arrangement of the connection plugs 13 as in the sixth embodiment. The connection plugs 13 can have a layout capable of obtaining a high wiring routing efficiency or appropriate overlap between each driving circuit of a driving circuit layer 11 and a corresponding electrode structure 30 (first electrode 14) in the layout. For example, in a case in which the electrode structure 30 is hexagonal, and elements included in the driving circuit are arranged in the X and Y directions, the region necessary for the connection between the electrode structure 30 and the elements included in the driving circuit can be made small using the arrangement as shown in FIG. 14.

The display device 100 as described above can be incorporated in various electronic devices. Examples of such an electronic device are a camera, a computer, a portable terminal, and an onboard display device. The electronic device can include, for example, the display device 100 and a driving circuit that drives the display device 100.

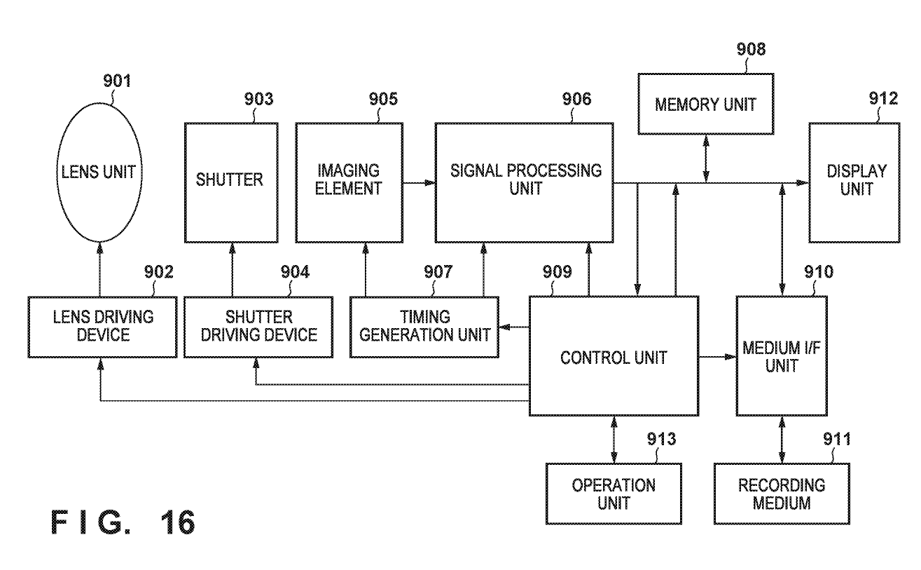

An embodiment in which the above-described display device is applied to a digital camera will be described with reference to FIG. 16. A lens unit 901 is an imaging optical system that forms an optical image of an object on an imaging element 905, and includes a focus lens, a zoom lens, a stop, and the like. Driving of the focus lens position, the zoom lens position, the opening diameter of the stop, and the like in the lens unit 901 is controlled by a control unit 909 via a lens driving device 902.

A mechanical shutter 903 is arranged between the lens unit 901 and the imaging element 905, and its driving is controlled by the control unit 909 via a shutter driving device 904. The imaging element 905 is arranged to receive light that enters from the lens, and converts an optical image formed by the lens unit 901 into an image signal by a plurality of pixels.

A signal processing unit 906 receives the image signal output from the imaging element 905, and performs A/D conversion, demosaicing processing, white balance adjustment processing, encoding processing, and the like for the image signal. The signal processing unit 906 also executes focus detection processing of detecting a defocus amount and direction by a phase difference detection method based on a signal obtained from the image signal output from the imaging element 905.

A timing generation unit 907 outputs various kinds of timing signals to the imaging element 905 and the signal processing unit 906. The control unit 909 includes, for example, memories (ROM and RAM) and a microprocessor (CPU), and implements various kinds of functions of the digital camera by loading a program stored in the ROM into the RAM and causing the CPU to execute it to control the units. The functions implemented by the control unit 909 include automatic focus detection (AF) and automatic exposure control (AE). The control unit 909 receives a signal based on the signal output from the imaging element 905, and inputs a signal for an electronic viewfinder to a display unit 912.

A memory unit 908 is used by the control unit 909 or the signal processing unit 906 to temporarily store image data or as a work area. A medium I/F unit 910 is an interface configured to perform read/write access to a recording medium 911 that is, for example, a detachable memory card. The display unit 912 is used to display a shot image or various kinds of information of the digital camera. An operation unit 913 includes user interfaces such as a power switch, a release button, and a menu button configured to allow a user to do an instruction or setting for the digital camera.

When the display device described in any one of the above-described embodiments is used in the display unit 912, an image to be shot can be displayed more accurately. A driving unit that drives the display device includes, for example, the control unit 909.

The operation of the digital camera at the time of image shooting will be described. When the power is turned on, a shooting standby state is set. The control unit 909 starts moving image shooting processing of causing the display unit 912 to operate as an electronic viewfinder and display processing. If a shooting preparation instruction (for example, half stroke of the release button of the operation unit 913) is input in the shooting standby state, the control unit 909 starts focus detection processing. For example, the control unit 909 can perform focus detection processing by a phase difference detection method. More specifically, the control unit 909 obtains an image shift amount based on the phase difference between signal waveforms obtained by combining signals of the same type of A image signals and B image signals obtained from a plurality of pixels, and obtains the defocus amount and direction.

The control unit 909 obtains the moving amount and the moving direction of the focus lens of the lens unit 901 based on the obtained defocus amount and direction, drives the focus lens via the lens driving device 902, and adjusts the focus of the imaging optical system. After the driving, focus detection based on a contrast evaluation value may be further performed as needed to finely adjust the focus lens position.

After that, if a shooting start instruction (for example, full stroke of the release button) is input, the control unit 909 executes a shooting operation for recording, processes obtained image data by the signal processing unit 906, and stores it in the memory unit 908. The control unit 909 records the image data stored in the memory unit 908 in the recording medium 911 via the medium I/F unit 910. Note that the image data may be output from an external I/F unit (not shown) to an external device such as a computer.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Applications No. 2016-233498, filed Nov. 30, 2016 and No. 2017-208514, filed Oct. 27, 2017, which are hereby incorporated by reference herein in their entirety.

What is claimed is:

1. A display device comprising:
an electrode structure including a first electrode arranged on a substrate, and a member arranged on the first electrode;
an insulator configured to cover a peripheral portion of the electrode structure;
an organic film configured to cover the first electrode and the insulator; and
a second electrode configured to cover the organic film,
wherein the member includes a first portion arranged in the peripheral portion of the electrode structure so as to cover a peripheral portion of an upper face of the first electrode, and
a reflectance of the peripheral portion of the electrode structure is lower than a reflectance of a central portion that is a portion inside the peripheral portion of the electrode structure.

2. The device according to claim 1, wherein the first electrode contains at least one of aluminum, silver, an aluminum alloy, and a silver alloy.

3. The device according to claim 1, wherein the member contains at least one of titanium and titanium nitride.

4. The device according to claim 1, wherein the member includes a second portion arranged at the central portion of the electrode structure so as to cover a central portion of the upper face of the first electrode.

5. The device according to claim 4, wherein a film thickness of the second portion is smaller than a film thickness of the first portion.

6. The device according to claim 4, wherein the organic film is arranged so as to be in contact with a side face of the first portion and an upper face of the second portion.

7. The device according to claim 1, further comprising:
a driving circuit arranged between the substrate and the first electrode and configured to drive the electrode structure; and
a connection plug configured to connect the driving circuit and the electrode structure,
wherein the connection plug is arranged in a region of the first portion in orthogonal projection to a surface of the substrate.

8. The device according to claim 7, wherein the insulator includes an opening that exposes the central portion of the electrode structure, and the organic film includes a portion arranged in the opening.

9. The device according to claim 1, wherein the first portion includes a first opening,
the insulator includes an opening at a position overlapping the first opening in a planar view, and
the organic film includes a portion arranged in the first opening and the opening so as to be in contact with a side face of the first portion facing the first opening.

10. The device according to claim 9, wherein the central portion of the upper face of the first electrode is in contact with the organic film.

11. The device according to claim 1, wherein the insulator includes a trench arranged between the electrode structure and an electrode structure adjacent to the electrode structure.

12. An electronic device comprising:
a display device of claim 1; and
a driving unit configured to drive the display device.

13. A display device comprising:
an electrode structure including a first electrode arranged on a substrate, and a member arranged on the first electrode and including a second portion that is a central portion having a film thickness smaller than a film thickness of a first portion that is a peripheral portion;
an insulator that covers the peripheral portion of the member;
an organic film that covers the electrode structure and the insulator; and
a second electrode that covers the organic film,
wherein the first electrode contains aluminum, and
the member contains titanium.

14. The device according to claim 13, wherein the organic film is arranged so as to be in contact with a side face of the first portion and an upper face of the second portion.

15. The device according to claim 13, further comprising:
a driving circuit arranged between the substrate and the first electrode and configured to drive the electrode structure; and
a connection plug configured to connect the driving circuit and the electrode structure,
wherein the connection plug is arranged in a region of the first portion in orthogonal projection to a surface of the substrate.

16. The device according to claim 15, wherein the insulator includes an opening that exposes the central portion of the electrode structure, and the organic film includes a portion arranged in the opening.

17. The device according to claim 13, wherein the insulator includes a trench arranged between the electrode structure and an electrode structure adjacent to the electrode structure.

18. An electronic device comprising:
a display device of claim 13; and
a driving unit configured to drive the display device.

19. A method of manufacturing a display device, comprising:
forming, on a substrate, a first electrode and a member layer on the first electrode;
forming an insulating film on the member layer;
removing a part of a portion of the insulating film overlapping the first electrode in a planar view using a mask to form an opening, thereby forming an insulating layer; and
removing a part of the member layer to form an opening in the member layer using the mask in the opening of the insulating layer, thereby forming a member.

20. The method according to claim 19, wherein when removing the part of the member layer, etch selectivity of the member layer to the insulating layer is not less than 5.
